(19) United States
(12) Patent Application Publication
(10) Pub. No.: US 2008/0042127 A1
(43) Pub. Date: Feb. 21, 2008

(54) Transition metal free coupling of highly fluorinated and non-fluorinated pi-electron systems

(76) Inventor: Mark D. Watson, Lexington, KY (US)

Correspondence Address: KING & SCHICKLI, PLLC, 247 NORTH BROADWAY, LEXINGTON, KY, 40507, US

(21) Appl. No.: 11/506,017

(22) Filed: Aug. 17, 2006

(51) Int. Cl. H01L 51/00; H01L 51/54; C08G 61/00; C09K 11/06

(52) U.S. Cl. 257/40; 528/401; 528/397; 528/12; 257/E51.028; 136/263; 313/504; 428/917

(57) ABSTRACT

A method for making an organic conjugated monomer, oligomer, polymer or small molecule includes reacting a silyl substituted pi-system compound with a highly fluorinated pi-system compound.

### FIELD OF INVENTION

The present invention relates generally to organic conjugated materials and, more particularly to novel compounds, methods for their production and electronic devices made with these compounds.

### BACKGROUND AND PRIOR ART

The commercial significance of organic conjugated polymers, and organic electronic materials in general is their promise as low-cost active components in consumer electronics including LEDs, RFID tags, thin-film transistors, sensors, and photovoltaic (solar cell) applications. [(a) B. W. D'Andrade, S. R. Forrest, Adv. Mater. 2004, 16, 1585-95. (b) S. R. Forrest, Nature 2004, 428, 911-918. (c) G. Hughes, M. R. Bryce, J. Mater. Chem. 2005, 15, 94-107. (d) H. E. Katz, Chem. Mater. 2004, 16, 4748-56. (e) H. E. Katz, Z. Bao, S. L. Gilat, Acc. Chem. Res. 2001, 34, 359-69. (f) T. W. Kelley, P. F. Baude, C. Gerlach, D. E. Ender, D. Muyres, M. A. Haase, D. E. Vogel, S. D. Theiss, Chem. Mater. 2004, 16, 4413-22. (g) A. P. Kulkarni, C. J. Tonzola, A. Babel, S. A. Jenekhe, Chem. Mater. 2004, 16, 4556-73.] It is not clear whether these markets will be dominated by polymeric or small-molecule materials. A recent online brochure posted by Cambridge Digital Technologies (CDT) maintains the long-touted technical advantage of polymers over small molecule materials due to more facile solution processing to large area films [D. Fyfe, T. Nicklin, A bright future: How chemicals drive the way we display information. http://www.raeng.org.uk/news/publications/ingenia/issue19/Fyfe.pdf accessed Aug. 7, 2006]. However, polymers cannot generally be obtained with the same high levels of purity obtainable with small molecules after sublimation, crystallization, or chromatography. In order to display their full potential, conjugated polymers must be prepared with higher initial purity by cleaner processes, since methods for post-synthesis purification are limited compared to small molecules.

The state of the art of organic conjugated polymer synthesis is dominated by transition-metal catalyzed reactions [for a review, see F. Babudri, G. M. Farinola, F. Naso, J. Mater. Chem. 2004, 14, 11-34.]. These provide many great advantages over classical organic transformations, but they are not perfect. Notable chemical defects resulting from transition metal-catalyzed reactions are incorporation of end groups from the catalyst ligands [(a) M. Remmers, B. Mueller, K. Martin, H.-J. Raeder, W. Koehler, Macromolecules 1999, 32, 1073-79. (b) T. I. Wallow, B. M. Novak, J. Org. Chem. 1994, 59, 5034-37.], homocoupling of monomers which are intended to cross-couple with another partner, and production of enyne groups during Sonogashira reactions. Functional “handles” used for building up the polymer backbones may be lost during polymerization limiting molecular weight, or may be present in the end, unfavorably altering properties (e.g. heavy atoms such as bromide/iodide). It has been shown that Palladium catalysts leave behind palladium nanoparticles, which are difficult to remove from some classes of conjugated polymers, and can be deleterious to electronic properties [F. C. Krebs, R. B. Nyberg, M. Jorgensen, Chem. Mater. 2004, 16, 1313-18; K. T. Nielsen, K. Bechgaard, F. C. Krebs, Macromolecules, 2005, 38, 658-59].

Regioselective reactions of nucleophiles with highly fluorinated pi-systems are a means to prepare organic electronic materials utilizing minimal reagents and without using transition metals, ligands, and many other additives currently required. An extremely broad range of nucleophiles and highly fluorinated pi-systems have been shown to be effective reaction partners [for a review, see G. M. Brooke, J. Fluor. Chem. 1997, 86, 1-76]. Reactions between chalcogenide nucleophiles and perfluorinated pi-systems have been exploited to make alternating copolymers [(a) P. M. Budd, B. S. Ghanem, S. Makhseed, N. B. McKeown, K. J. Msayib, C. E. Tattershall, Chem. Commun. 2004, 230-31. (b) J.-P. Kim, W.-J. Lee, J.-W. Kang, S.-K. Kwon, J.-J. Kim, J.-S. Lee, Macromolecules 2001, 34, 7817-21. (c) K. Kimura, Y. Tabuchi, A. Nishichi, Y. Yamashita, Y. Okumura, Y. Sakaguchi, Polymer J. 2001, 33, 290-96. (d) K. Kimura, Y. Tabuchi, Y. Yamashita, P. E. Cassidy, J. W. Fitch III, Y. Okumura, Poly. Adv. Technol. 2000, 11, 757-65], but most of these materials can not be used in the same applications as organic electronic materials due to limited electronic conjugation. Few analogous carbon-carbon bond-forming polymerizations are reported. Notable examples are oligomers and polymers obtained via reaction of perfluoroarenes with metalated ferrocenes [P. A. Deck, M. J. Lane, J. L. Montgomery, C. Slebodnick, F. R. Fronczek, Organometallics 2000, 19, 1013-24] or indene [P. A. Deck, C. R. Maiorana, Macromolecules 2001, 34, 9-13] and small molecules from lithiated thiophenes [D. J. Crouch, P. J. Skabara, et al Chem. Mater. 2005, 17, 6567-78]. The non-fluorinated monomers are made reactive (metallated) by deprotonation with strong bases. These require strictly anhydrous conditions, careful control of stoichiometry in one of the cases, and handling of a highly reactive and moisture-sensitive alkyl lithium or metal hydride. Reactive metallated monomers which are environmentally stable would be preferred.

The present invention relates to a novel method for the synthesis of a broad range of organic conjugated materials, more specifically to a method for bond formation between silyl-functionalized pi-electron systems and highly fluorinated pi-electron systems to produce monomeric, oligomeric, polymeric and small molecule electronically conjugated materials. The only required additional reagent is a fluoride source. The invention further relates to novel organic conjugated compounds and the application of those compounds as semiconductors, light-emitters, and energy or charge-transporters in (opto)electronic devices such as field effect transistors (FET), integrated circuits (IC), liquid crystal displays (LCD), photovoltaic devices (solar cells), radio frequency identification tags (RFID), and sensors.

### SUMMARY OF THE INVENTION

The present invention relates to a novel method for the preparation or synthesis of organic conjugated monomers, oligomers, polymers and small molecules by coupling a highly fluorinated pi-electron system compound with a silyl-functionalized pi-electron system compound, in which the silicon group is attached to sp- or sp²-hybridized atoms. More specifically, the method comprises reacting, in the presence of a fluoride source, (1) a silyl substituted π-system compound with chemical formula

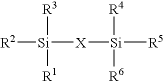

where x is defined as alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof and R¹-R⁶ are the same or different alkene, alkyne, aryl, hetaryl, imine, and combinations thereof or are substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof with (2) a highly fluorinated pi-system which may be defined as alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof with 2-20 fluorine atoms attached directly to the pi-system. The fluoride source may be any organic or inorganic fluoride salt. Perfluorinated pi-system compounds useful in the present invention include but are not limited to the following

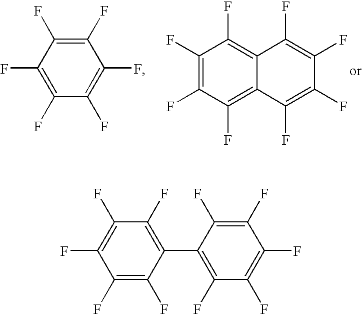

In accordance with yet another aspect, the present invention includes monomers, oligomers, polymers and small molecules made in accordance with the present method.

In accordance with yet another aspect of the present invention, a polymerizable liquid crystal material, an anisotropic polymer film, a semiconductor, a transistor such as a field effect transistor (FET), an organic field effect transistor (OFET) and a thin film transistor (TFT), a photovoltaic device, an eluminescent material, an organic light emitting diode (OLED), a liquid crystal display (LCD), a radio frequency identification tag (RFID) and an integrated circuit (IC) including one or more monomers, oligomers, polymers and small molecules made by the present method are also provided.

### BRIEF DESCRIPTION OF THE DRAWING FIGURES

The accompanying drawings incorporated in and forming a part of the specification illustrates several aspects of the present invention and together with the description serves to explain certain principles of the invention. In the drawings:

FIG. 1 is a schematical representation of a thin film transistor of the present invention; and

FIG. 2 is a schematical representation of a photovoltaic device of the present invention.

Reference will now be made in detail to the present invention as illustrated in the drawing figures.

### DETAILED DESCRIPTION OF THE INVENTION

The current invention relates to a bond forming reaction which is particularly well-suited to the preparation of organic conjugated monomers, oligomers, polymers and small molecules. The coupling reaction occurs between highly fluorinated pi-electron systems and silyl-functionalized pi-electron systems, in which the silicon group is attached to sp- or sp²-hybridized atoms. With each new bond-formation, the reagent which induces the reaction (fluoride ion) is regenerated. The reaction therefore requires only a minute (catalytic) amount of fluoride to produce, in high yields, small molecules, oligomers, and high-molecular weight polymers. Chemically pure polymers are produced with well-defined end-groups. High purity is also possible because the fluoride ion source and the sole side product (a fluorosilane) are very easily removed by washing with water and evaporation, respectively. The reaction is a highly attractive alternative to transition-metal catalyzed reactions which currently dominate the field.

Classes of monomers, oligomers, and polymers for which this method will be useful include, but are not limited to, alternating copolymers of thiophene and other hetarylenes, poly(arylene ethynylene)s, and poly(arylene vinylene)s. The method is a transition-metal-free alternative to many of the common transition-metal-catalyzed reactions for polymer synthesis such as: Suzuki, Sonogashira, Heck, Stille, GRIM, Hiyama, Yamamoto, etc. Practical advantages are simpler and in some cases more environmentally benign monomer synthesis, drastic minimalization of expensive additives for polymerization, and it produces highly pure polymeric materials. Minimal purification is needed to remove the single side product (a fluorosilane) and the active ingredients which afford the polymerization. All these facets make the process and the materials produced thereby, highly industrially feasible.

The proposed general route to prepare copolymers with alternating pi-electron units and perfluorinated pi-electon units is depicted below. Defect-free polymers result from the regioselective reaction of perfluoroarenes[G. M. Brooke, J. Fluor. Chem. 1997, 86, (1), 1-76.] with nucleophiles, which are generated in this case by the action of fluoride [(a) B. A. Omotowa, J. n. M. Shreeve, Organometallics 2000, 19, (14), 2664-2670. (b) G. K. S. Prakash, A. K. Yudin, Chem. Rev. 1997, 97, (3), 757-786.] on silicon atoms attached to sp- and sp²-hybridized atoms within pi-electron systems. Because fluoride ion is regenerated with each new bond formation, only catalytic amounts of fluoride are needed.

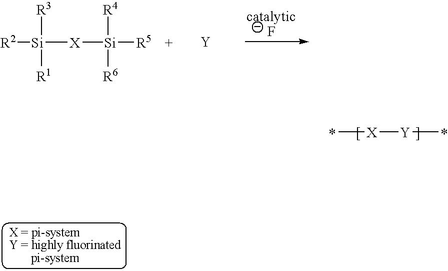

where x or pi-System may be defined as alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof. R¹−R⁶=the same or different alkene, alkyne, aryl, hetaryl, imine, and combinations thereof or are substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof. The Y or highly fluorinated pi-system may be defined as alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof with 2-20 fluorine atoms attached directly to the pi-system. During the course of the reaction, fluorides in the highly fluorinated pi-systems are replaced as new bonds are formed to the pi-system. The fluoride source may be any organic or inorganic fluoride salt.

The present method advantageously effects coupling under very mild conditions, with minimal amounts of easily handled reagents, and leading to electronically conjugated materials. We demonstrate here for the first time that the activation of silyl groups by fluoride ion leads to bond formation between electronic pi-systems. Just as in the case of transition-metal-catalyzed reactions, the non-fluorinated monomers must be functionalized with a reactive group to allow coupling reactions. Silylation necessary for the current invention is no more difficult or expensive than the typical functionalizations, and can in many cases be completed in fewer steps. The highly fluorinated pi-electron systems, which serve as reaction partners, require no additional functionalization.

Given the broad interest in functionalized, highly fluorinated pi-electron systems in such diverse fields as ligands for transition-metal catalysts and pharmaceuticals, the invention disclosed herein is expected to be an important addition to the available synthetic tools for a broad range of small-molecule materials as well.

### Examples of Application of the Described Synthetic Method

Representative procedures for the synthesis of alternating PPE's and thiophene copolymers are given below. These are only examples to demonstrate the success of this synthetic route, and are not meant to limit in any way the scope of the claims made herein. Reactions may be completed with different sources of fluoride, solvents, temperature, and monomers. The most convenient/cost-effective, and therefore preferred, combinations allow polymerization at room temperature, and even can be conducted in open air using off-the-shelve solvents and reagents. Finally, examples of the preparation of well-defined small molecules and an oligomer are presented. One of the small-molecule examples demonstrates the conversion of a valuable organic electronic material, an anthradithiophene, [M. M. Payne, S. R. Parkin, J. E. Anthony, C.-C. Kuo, T. N. Jackson, J. Am. Chem. Soc. 2005, 127, 4986-87] from one color, red, to a blue product, with associated change in solution photoluminescence from orange to an intense, bright red. The new product was isolated in essentially pure form after minimal purification. Any person skilled in the art will realize that these procedures are equally applicable to a variety of other non-fluorinated and fluorinated pi-electron systems and are equally applicable to the synthesis of small molecules, not only polymers.

A highly related synthetic methodology is the Hiyama coupling reaction [for reviews see (a) T. Hiyama, J. Organomet. Chem. 2002, 653, 58-61; (b) S. E. Denmark, M. H. Ober, Aldichimica Acta, 2003, 36, 75-85]. This procedure also induces carbon-carbon bond formation between silyl-functionalized pi-electron systems and halogenated pi-electron systems (halogen=iodine, bromine, chlorine, as well as pseudo-halogens like perfluoroalkylsulfonates). This method however requires stoichiometric (or more) amounts of fluoride or other activators, and a transition metal catalyst, usually Palladium-based. The carbon-silicon bond is induced by fluoride ion, or other nucleophiles, to transfer the pi-electron system to a Palladium center. The palladium center carrying the pi-electron system then effects bond-formation with another pi-electron system carrying any of the halogens (iodine, bromine, chlorine), excluding fluorine, or a pseudo-halogen (e.g. perfluoroalkyl sulfonates). This methodology appears nearly universally effective for any type of silyl-functionalized pi-electron system and demonstrates that with appropriate conditions, most any silyl-functionalized pi-electron systems can be activated to couple with most any substrate. The following is a rather brief list of examples of published successful Hiyama coupling reactions.

1. triallyl(aryl)silanes coupled with aryl halides [Y. Nakao, T. Oda, A. K. Sahoo, T. Hiyama, J. Organomet. Chem. 2003, 687, 570-73]

2. alkenylsilanols coupled with aryl-triflates and nonaflates [S. E. Denmark, R. F. Sweis, Org. Lett. 2002, 4, 3771-74.]

3. alkenylsilanes coupled with aryl halides to produce poly(phenylene vinylenes) [H. Katayama, M. Nagao, R. Moriguchi, F. Ozawa, J. Organomet. Chem. 2003, 676, 49-54.]

4. 2-indolyldimethyl silanols coupled with aryl halides[S. E. Denmark, J. D. Baird, Org. Lett., 2004, 6, 3649-52]

5. Silylethenyl carbazoles coupled with aryl halides [B. Marciniec, M. Majchrzak, W. Prukala, M. Kubicki, D. Chadyniak, J. Org. Chem. 2005, 70, 8550-55.

6. Pyridyl silanes coupled with aryl halides [P. Pierrat, P. Gros, Y. Fort, Org. Lett. 2005, 7, 697-700].

Anyone skilled in the art may ascertain from these examples of Hiyama coupling, taken together with specifice examples of application of the current invention provided herein, that the latter method, due to similarities in its mode of operation to that of the Hiyama coupling, will enjoy a broad scope of applicability, as claimed herein. In fact, the scope of the invention described herein has already been shown to extend beyond that of the related Hiyama coupling, in that it is able to induce coupling between trimethylsilyl-functionalized thiophenes, which failed to undergo Hiyama coupling (see specific examples).

Materials and Methods. Unless otherwise specified, all reagents, solvents, and chemicals were purchased from Aldrich Chemical Company or Acros Organics. All fluorinated aromatics were purchased from Apollo Scientific Ltd. Trimethyl silyl acetylene was purchased from GFS Chemicals and Cl₂Pd[dppf] from Strem Chemicals. CsF and 18-crown-6 were each dried under reduced pressure (<10⁻³ mbar) at 180° C. and 80° C., respectively and stored in an argon-filled glove box. Tetrabutylammonium fluoride (TBAF) was purchased as its hydrate, and as an anhydrous solution in THF which was stored in an argon-filled glove box. C₆F₆ and toluene were distilled from CaH₂ and sodium/potassium alloy, respectively, and stored over molecular sieves under argon. Monomers 4 and 8 were prepared as published [Y. Wang, M.D. Watson, J. Amer. Chem. Soc. 2006, 128, 2536-37]. Compound 15 was donated by John Anthony, University of Kentucky, Lexington, Ky., after preparation by a modified published procedure [M. M. Payne, S. A. Odom, S. R. Parkin, J. E. Anthony, Org. Lett. 2004, 6, 3325.] All other materials were used as purchased. Unless otherwise stated, all manipulations and reactions were carried out under argon atmosphere using standard Schlenk techniques. ¹H, ¹³C, and ¹⁹F NMR spectra were recorded on a Varian INOVA 400 MHz spectrometer (purchased under the CRIF Program of the National Science Foundation, grant CHE-9974810). Chemical shifts were referenced to residual protio-solvent signals, except for ¹⁹F spectra, where CCl₃F was added as internal standard and set to delta=0 ppm. Relative molecular weight determinations were made using a Waters 600E HPLC system, driven by Waters Empower Software and equipped with two linear mixed-bed GPC columns (American Polymer Standards Corporation, AM Gel Linear/15) in series. Eluting polymers were detected with both refractive index and photodiode array detectors. The system was calibrated with 11 narrow PDI polystyrene samples in the range 580-2×10⁶ Da with toluene at a flow rate of 1 mL/min.

### Alternating Copolymers

### Alternating Poly (Phenylene Ethynylene)s

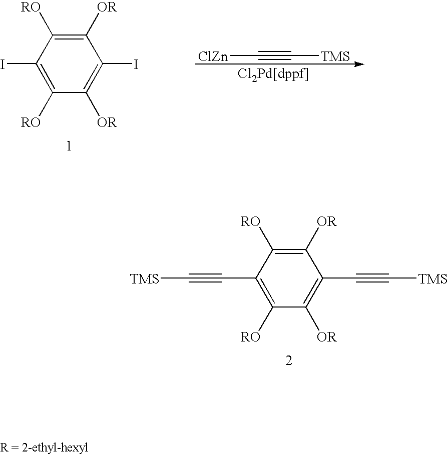

TMS in this, and all subsequent examples, refers to trimethylsilyl Compound 2. In a dry vacuum flask cooled in an ice bath, a solution of BuLi (14.2 mL, 1.6 M hexanes, 22.7 mmol) was added slowly via syringe to TMS-acetylene (3.64 mL, 23.9 mmol) in THF (20 mL) and stirred for 3 hours. Anhydrous ZnCl₂ (3.43 g, 25.6 mmol) was added to the flask. After stirring an additional 45 minutes, compound 1 (4.8 g, 5.69 mmol) [prepared by a modified published procedure according to E. M. D. Keegstra, B.-H. Huisman, E. M. Paardekooper, F. J. Hoogesteger, J. W. Zwikker, L. W. Jenneskens, H. Kooijman, A. Schouten, N. Veldman, A. L. Spek, J. Chem. Soc., Perkin Trans 2, 1996, 2, 229-40] was added and the solution was deoxygenated by pump/purge with argon, followed by the addition of Cl₂Pd[dppf] (233 mg, 0.27 mmol). The vessel was sealed and submersed in a 110° C. oil bath for 48 hours. The contents were poured into water, extracted with hexanes (2×150 mL), and the combined extracts dried over MgSO₄, filtered, then concentrated under reduced pressure. The concentrated solution was purified via column chromatography (silica gel, pentane/CH₂Cl₂ 5:1) and a pale yellow liquid was recovered (2.62 g, 59%). ¹H NMR (200 MHz, CDCl₃) δ 3.88(m, 8H,), 1.62 (m,10H), 1.7-1.2 (m, 36H), 0.93 (m, 24H,) 0.21 (s, 18H). ¹³C NMR (50 MHz, CDCl₃) δ 149.98, 114.22, 103.98, 96.91, 76.09, 40.23, 29.99, 29.03, 23.42, 22.84, 13.84, 10.87, −0.36.

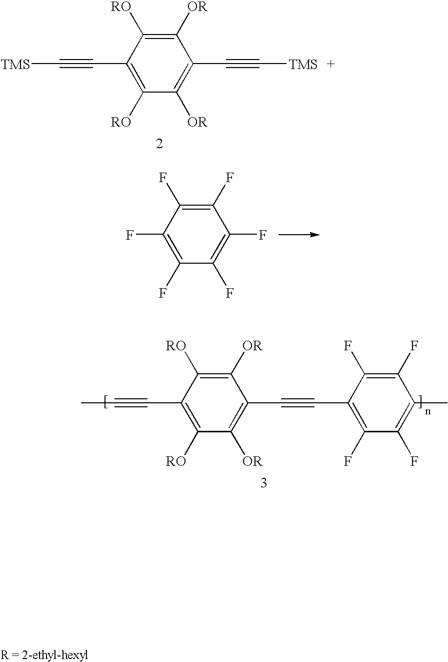

Polymer 3 (Method A, TBAF, anhydrous conditions). In an argon-filled glove box, monomer 2 (205 mg,0.2617 mmol), toluene (5 ml), C₆F₆ (32 μL, 1.05 eq), and dry TBAF (1M solution in THF, 13.085 μL, 0.05 eq) were combined in a vacuum flask containing a magnetic stir bar. The vessel was sealed and the contents stirred at room temperature for 48 hours. Methanol was added to precipitate the polymer. The polymer was re-dissolved in toluene and re-precipitated with methanol, then dried under vacuum overnight to give a bright yellow powder (142 mg). ¹H NMR (CDCl₃) δ 3.938 (br, 8H), δ 3.498 (s, 0.14H, acetylenic end groups), 1.79 (m,4H), 1.57+1.45+1.26 (m+m+m, 28H), 0.884+0.839 (tr+tr,24H); ¹⁹F NMR (CDCl₃)δ −136.65 (br,786 F), −152.51 (tr,2 F, end-group), −162.16 (m,4 F, end-group); ¹³C (CDCl₃) δ 150.18, 146.47 (d of m), 114.45, 105.04 (m) 96.27 (tr), 83.84, 77.93, 40.38, 30.19, 29.16, 23.46, 23.06, 14.06, 10.96. The following weak signals are from end-groups from desilylated monomer 2: ¹³C (CDCl₃) δ 150.38, 150.34, 115.26, 113.21, 78.13, 77.76. Mₙ=25 kDa (PDI=1.7)
Polymer 3 (Method B, CsF, anhydrous conditions). In an argon-filled glove box, monomer 2 (200 mg,0.255 mmol), dry toluene (5 ml), dry CsF (3.87 mg, 0.0255 mmol, 0.1 eq)), 18-crown-6 (13.5 mg, 0.051 mmol, 0.2 eq), and C₆F₆ (31 μL, 0.266 mmol, 1.05 eq) were combined in a vacuum flask containing a magnetic stir bar. The vessel was sealed and the contents stirred at 60° C. for 200 hours. The bright yellow polymer was isolated as above in near quantitative yield (196 mg). ¹H NMR (CDCl₃) δ 3.981 (br,8H), 3.498 (s, 0.07H, acetylenic end groups), 1.784 (m, 4H), 1.65-1.25 (br,28H), 0.881+0.837 (tr+tr,24H), 0.05 (s, 0.61H, TMS end group); ¹⁹F NMR (CDCl₃)δ −136.53 (br)−152.49 (tr,2 F, end-group), −162.11 (m,4 F, end-group); ¹³C (CDCl₃) δ 150.20, 146.48 (d of m), 114.45, 105.04 (m) 96.27 (tr), 83.84, 77.93, 40.38, 30.19, 29.15, 23.46, 23.05, 14.03, 10.97, 0.13 (weak, TMS endgroups). Mₙ=29 kDa (PDI=2.7)
Polymer 3 (Method C, TBAF-hydrate, ambient conditions). In open air in a small vial containing a magnetic stir bar, compound 2 (120 mg,0.153 mmol), toluene (5 ml), C₆F₆ (18.68 μL, 0.153 mmol), and TBAF-hydrate (˜3 mg) were combined. The vial was sealed to avoid evaporation, and the mixture was stirred at room temperature for 48 hours. The bright yellow polymer (100 mg) was isolated as above. ¹H NMR (CDCl₃) δ 3.981 (br, 8H), δ 3.499 (s, 0.19H, acetylenic end groups), 1.776 (m,4H), 1.62-1.20 (m+m+m, 28H), 0.881+0.837 (tr+tr,24H); ¹⁹F NMR (CDCl₃)δ −136.65 (br); ¹³C (CDCl₃) δ 150.20, 146.48 (d of m), 114.45, 105.06 (m) 96.29 (tr), 83.82, 77.93, 40.38, 30.18, 29.15, 23.45, 23.05, 14.03, 10.97. The following weak signals are from end-groups from desilylated monomer 2: ¹³C (CDCl₃) δ 150.40, 150.36, 115.27, 113.22, 87.37, 83.13, 76.77, 40.44, 30.25, 23.55, 23.12, 14.13, 11.134. DP˜10 units based on ¹H NMR.

### Alternating Thiophene Copolymers

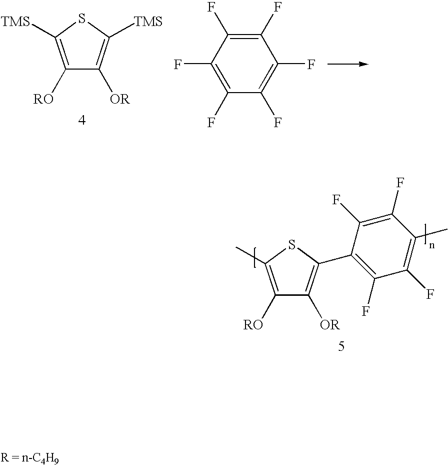

Polymer 5 (Method A, 80° C.). In an argon-filled glove box, monomer 4 (110 mg, 0.295 mmol), C₆F₆ (40.93 μL, 1.2 eq), CsF (4.69 mg, 0.1 eq), 18-crown-6 (15.59 mg, 0.2 eq), and toluene (4 mL) were combined in a vacuum flask containing a magnetic stir bar. The vessel was sealed and the contents stirred at 80° C. for 5 days. The solution was extracted with deionized water twice and the polymer precipitated by pouring the solution in 50 mL methanol. The polymer was re-dissolved in chloroform then precipitated again into methanol. After drying under reduced pressure, the polymer was obtained as a colorless solid (123 mg). ¹H NMR (CDCl₃) δ: 4.12 (m, 4H), 1.65 (m, 4H), 1.39 (m, 4H), 0.90 (m, 6H). ¹³C NMR (CDCl₃) δ: 148.77, 144.32 (d of m), 112.37 (m), 110.75, 73.02, 31.90, 18.92, 13.72. ¹⁹F NMR (CDCl₃) δ: −137.94 (m, 4 F), −138.81 (m, 147 F), −153.41 (m, 2 F), −162.24 (m, 4 F). Mₙ=28 kDa (PDI=2.7)
Polymer 5 (Method B, room temperature). Conducted exactly as in “Method A” above, except stoichiometry based upon 104 mg monomer 4, and entire reaction conducted at room temperature. Yield=80 mg. Spectroscopic data consistent with the above reaction at 80° C. except for small differences in integral values in the ¹⁹F NMR. Mₙ=23 kDa (PDI=3.1)

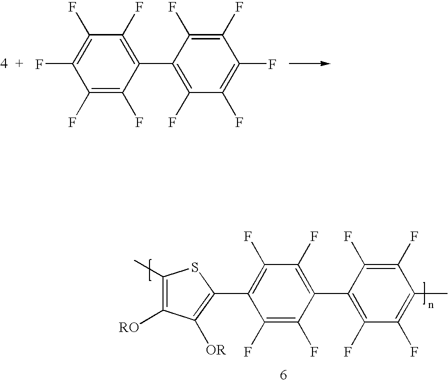

Polymer 6. In an argon-filled glove box, monomer 4 (106.7 mg, 0.286 mmol) decafluorobiphenyl (100.33 mg, 1.05 eq), CsF (4.55 mg. 0.1 eq), 18-crown-6 (15.12 mg, 0.2 eq) and toluene (1 mL) were combined in a vacuum flask containing a magnetic stir bar. The vessel was sealed and the contents stirred at 80° C. for 7 days. The polymer was obtained as a colorless powder after purification as described above (148 mg).
¹H NMR (C₂D₂Cl₄) δ: 4.13 (t, 4H), 1.64 (m, 4H), 1.36 (m, 4H), 0.90 (t, 6H). ¹³C NMR (C₂D₂Cl₄) δ: 148.81, 144.08 (d of m), 113.98 (m), 110.57, 106.79 (m), 73.09, 31.67, 18.81, 13.59. ¹⁹F NMR (C₂D₂Cl₄)δ: −137.36 (m, 65 F), −138.26 (m, 65 F), −149.94 (m, 2 F), −160.42 (m, 4 F). Mₙ=17 kDa (PDI=3.9)

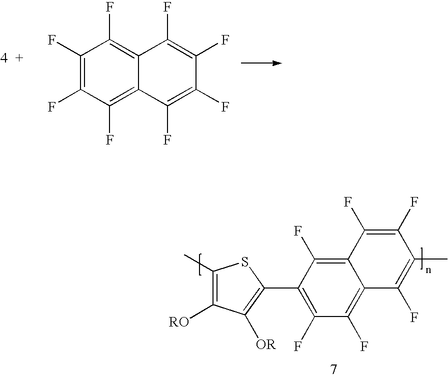

Polymer 7. In an argon-filled glove box, monomer 4 (105.6 mg, 0.283 mmol), octafluoronaphthalene (80.85 mg, 1.05 eq), CsF(4.50 mg, 0.1 eq), 18-crown-6 (14.96 mg, 0.2 eq) and toluene (1 mL) were combined in a vacuum flask containing a magnetic stir bar. The vessel was sealed and the contents stirred at 80° C. for 7 days, during which time it precipitates. The polymer was obtained as a colorless powder after purification as described above (116 mg). ¹H NMR (C₂D₂Cl₄) δ: 4.12 (broad, 4H), 1.61 (broad, 4H), 1.35 (broad, 4H), 0.86 (broad, 6H). ¹³C NMR (C₂D₂Cl₄) δ: 149.67 (d of m), 148.83, 144.82 (d of m), 140.82 (d of m), 111.45 (m), 110.75, 72.94, 31.73, 18.79, 13.65. ¹⁹F NMR (C₂D₂Cl₄) δ: Three signals with equivalent integral values: −116.46(m), −134.95(m), −147.15(m), There were an additional 10 small ¹⁹F signals arising from nonregiospecific addition (3 signals) and perfluoronaphthalene end groups (7 signals): −113.43(m), −115.77(m), −132.11(m), −133.65(m), −143.53(m), −146.09(m), −148.66(m), −149.18(m), −152.53(m), −155.10(m). M=20 kDa (PDI=3.4)

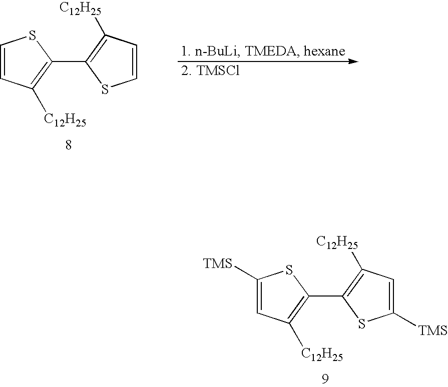

Compound 9. n-BuLi (3.35 mL, 1.6M in hexanes, 2.02 eq) was added drop-wise to a solution of compound 8 (1.34 g, 2.66 mmol) [prepared by modified published procedure according to Heterocycles 1991, 32, 1805] in 10 mL hexanes with 0.81 mL (2.02 eq) TMEDA maintained at room temperature. After stirring at room temperature for 30 minutes, then at reflux for 2 hr, TMSCl (0.84 mL, 2.5 eq) was added drop-wise into the suspension and the whole was stirred overnight at room temperature. The mixture was extracted with 10% HCl (aq) and deionized water, dried over MgSO₄, and concentrated via rotary evaporation. 5,5′-bis(trimethylsilyl)-3,3′-didodecyl-2,2′-bithiophene Compound 9 was isolated after flash chromatography [silica gel, pentane] as a yellow oil (1.68 g, 96.3%). ¹H NMR (CDCl₃) δ: 7.08(s, 2H), 2.51 (t, 4H), 1.27 (m, 40H), 0.89 (t, 6H), 0.33 (s, 18H). ¹³C NMR (CDCl₃) δ: 142.95, 139.92, 135.56, 134.57, 31.93, 30.85, 29.69, 29.67, 29.58, 29.53, 29.41, 29.37, 28.77, 22.69, 14.12, −0.063. GC-MS: m/z: 646 (C₃₈H₇₀S₂Si₂⁺, 100%).

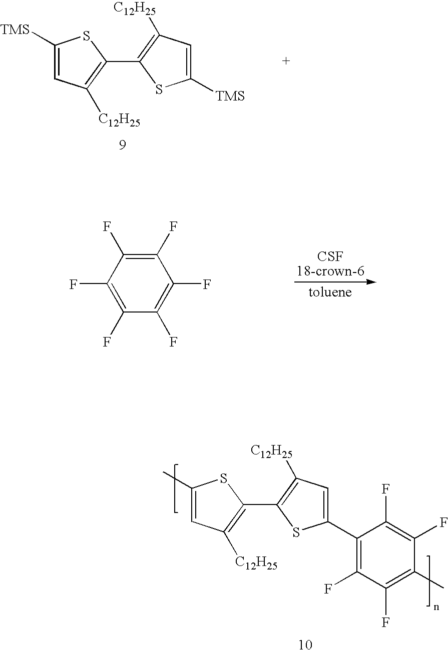

Polymer 10. In an argon-filled glove box, compound 9 (86.50 mg, 0.134 mmol), C₆F₆ (17.03 μL, 1.1 eq), CsF (2.13 mg, 0.1 eq), 18-crown-6 (7.08 mg, 0.2 eq), and toluene (1 mL) were combined in a vacuum flask containing a magnetic stir bar. The vessel was sealed and the contents stirred at 80° C. for 5 days. The solution was extracted with deionized water three times and the polymer precipitated by pouring the solution in 50 mL methanol. The polymer was re-dissolved in chloroform then precipitated again into methanol (2×). After drying under reduced pressure, the polymer was obtained as an orange to red solid (60 mg). ¹H NMR (CDCl₃) δ: 7.60 (s, 2H), 2.64 (broad m, 4H), 1.25 (m, 40H), 0.87 (t, 6H). ¹⁹F NMR (CDCl₃) δ: −140.19 (m, 4 F), −140.97 (m, 92 F), −156.41 (m, 2 F), −162.55 (m, 4 F). Mₙ(GPC)=27 kDa, (PDI=2.7).

### Small Molecules and Oligomers

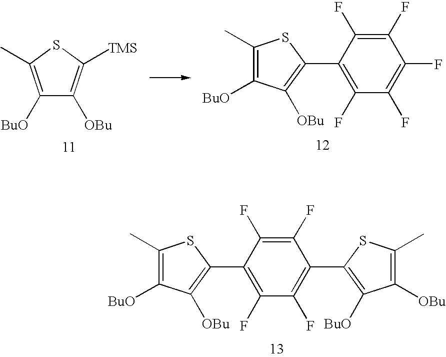

Compounds 12 and 13. In an argon-filled glove box, compound 11 (380 mg, 1.21 mmol), C₆F₆ (140 μL, 1.21 mmol), CsF (18.4 mg, 0.1 eq), 18-crown-6 (63.9 mg, 0.2 eq), and toluene (2 mL) were combined in a vacuum flask containing a magnetic stir bar. The vessel was sealed and after heating to 80° C. overnight, 11 was completely consumed (as determined by GC-MS). The reaction mixture was concentrated under reduced pressure to an oily residue, which was subjected to flash chromatography on silica gel with pentane-dichloromethane (3:1, v/v) to give compound 12 as a pale yellow liquid (217 mg, 0.531 mmol) and 13 as a colorless solid (183 mg, 0.290 mmol). The total isolated yield based on 8 was 92%. Compound 12: ¹H NMR (CDCl₃) δ: 4.012(t, 2H), 4.009(t, 2H), 2.36(s, 3H), 1.74(m, 2H), 1.57(m, 4H), 1.33(m, 2H), 0.999(t, 3H), 0.879(t, 3H). ¹⁹F NMR (CDCl₃) δ: −138.74(m, 2 F), −155.27(m, 1 F), −163.09(m, 2 F). ¹³C NMR (CDCl₃) δ: 148.92, 145.68, 144.79 (d of m), 140.77 (d of m), 137.64(d of tr), 124.72, 108.46 (m), 102.11, 73.29, 72.36, 32.17, 31.87, 19.19, 18.90, 13.82, 13.62, 11.91. GC-MS: m/z 408 (C₁₉H₂₁F₅O₂S⁺), 296 (100%). Compound 13: ¹H NMR (CDCl₃) δ: 4.03(m, 8H), 2.37(s, 6H), 1.78(m, 4H), 1.57(m, 8H), 1.35(m, 4H), 1.002(t, 6H), 0.886(t, 6H). ¹⁹F NMR (CDCl₃)δ: −140.24(s, 4 F). ¹³C NMR (CDCl₃) δ: 148.80, 145.66, 144.25 (d of m), 124.55, 112.44 (m), 103.46, 73.24, 72.33, 32.15, 31.88, 19.17, 18.89, 13.84, 13.66, 11.93. GC-MS: m/z 630 (C₃₂H₄₂F₅O₄S₂⁺), 406(100%).

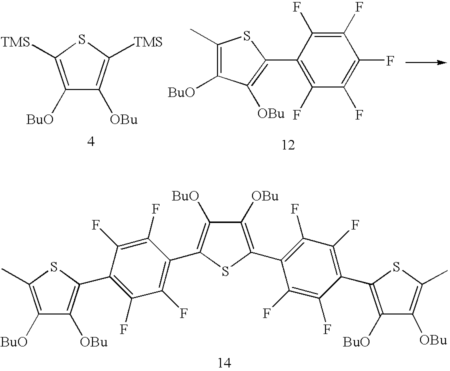

Oligomer 14. In an argon-filled glove box, compound 4 (100.2 mg, 0.269 mmol), compound 12 (109.8 mg, 0.269 mmol), CsF (4.1 mg, 0.1 eq), 18-crown-6 (14.2 mg, 0.2 eq), and toluene (1 mL) were combined in a vacuum flask containing a magnetic stir bar. The vessel was sealed and the contents stirred at 80° C. overnight. The reaction mixture was concentrated under reduced pressure to an oily residue, which was subjected to column chromatography on silica gel with pentane-dichloromethane (3:1, v/v) to give compound 14 as a pale yellow liquid (100 mg, 74% based on compound 4). ¹H NMR (CDCl₃) δ: 4.06 (overlapping triplets, 12H), 2.38 (s, 6H), 1.76-1.33 (overlapping multiplets, 24H), 1.00 (t, 6H), 0.90 (t, 6H), 0.89 (t, 6H). ¹⁹F NMR (CDCl₃)δ: −139.59 (m). ¹³C NMR (CDCl₃) δ: 148.98, 148.60, 145.73, 144.26 (d of m), 124.89, 113.45 (m), 111.43 (m), 110.70, 103.31, 73.31, 72.92, 72.40, 32.17, 31.92, 31.90, 19.19, 18.92, 18.90, 13.87, 13.70, 13.68, 12.00. MALDI: m/z: 1004(C₅₀H₆₀F₈O₆S₃⁺), 912(100%).

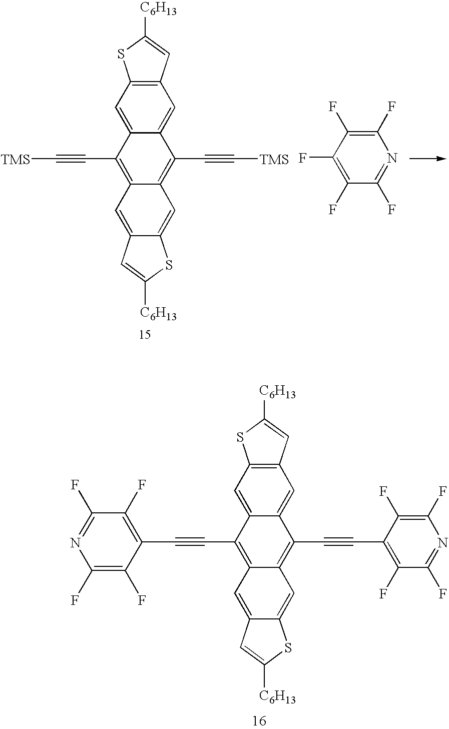

Anthradithiophene 16. Red crystals of compound 15 (10.6 mg) were combined with perfluoropyridine (0.017 ml, 10 eq), one tiny crystal of tetramethyl ammonium fluoride, and anhydrous THF (2 mL). After 2 hours of reaction, the originally red solution had become a maroon to purple suspension. A small aliquot was removed and diluted with THF. UV/Vis absorption measurements showed an absorption profile similar to that of 15, but bathochromically shifted by approximately 65 nm and broadened. After stirring overnight at room temperature, water was added to completely precipitate the product. The resulting solid was stirred with methanol, the supernatant was discarded, and 16 was isolated as a deep blue microcrystalline solid (11.68 mg, 89% yield). ¹H NMR (C₂D₂Cl₄, 75° C.) δ: 8.88 (d, 2H), 8.76 (d, 2H), 7.10 (s, 2H), 2.93 (t, 4H), 1.80 (m, 4H), 1.46-1.22 (overlapping multiplets, 12H), 0.88 (t, 6H). ¹⁹F NMR (C₂D₂Cl₄, 75° C.)δ: −90.59 (m, 4 F), −138.28 (m, 4 F).

The compounds of the present invention are useful as optical, electronic and semiconductor materials. Specifically, they may be used as charge transport materials in field effect transistors, as components of integrated circuits, radio frequency identification tags and organic light emitting diodes, in ultruluminescent display applications, in liquid crystal displays, in photovoltaic devices (solar cells), or sensors.

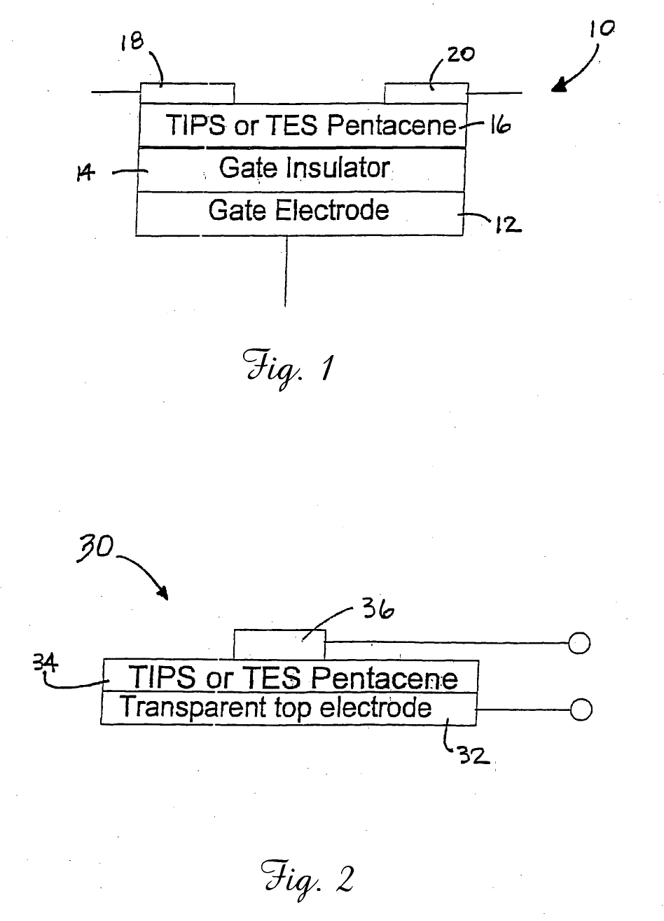

An example of a thin-film transistor is illustrated in FIG. 1 and an example of a photovoltaic device is illustrated in FIG. 2. The thin-film transistor 10 is comprised of a gate electrode 12 of a type known in the art, an insulator 14 and a semiconductor 16 in the form of a thin layer or film of the compounds of the present invention. In addition, the transistor 10 includes a conductive source electrode 18 and a drain electrode 20 both operatively connected to the semiconductor 16.

The insulator 14 may, for example, be a dielectric or metal oxide or even an insulating polymer like poly (methylmethacrylate). The conducting source and drain electrodes 18, 20 may be metals known in the art to be useful as electrodes, heavily doped semiconductors such as silicon or even a conducting polymer.

The photovoltaic device 30 comprises a transparent conductive electrode 32, a semiconductor 34 in the form of a thin layer or film of the compound of the present invention and a bottom electrode 36. The bottom electrode 36 may either be constructed from, a low work-function metal (aluminum, magnesium, calcium, etc.) to form a diode-like device or a higher work-function metal (e.g. gold, silver) to form an ohmic contact to the semiconductor 34.

The foregoing description of some preferred embodiments of the invention has been presented for purposes of illustration and description. It is not intended to be exhaustive or to limit the invention to the precise form disclosed. Obvious modifications or variations are possible in light of the above teachings. The embodiments were chosen and described to provide the best illustration of various principles of the invention and its practical application to thereby enable one of ordinary skill in the art to utilize the invention in various embodiments and with various modifications as is suited to the particular use contemplated. All such modifications and variations are within the scope of the invention as determined by the appended claims when interpreted in accordance with breadth to which they are fairly, legally and equitably entitled.

What is claimed:

1.) A method of making an organic conjugated monomer, oligomer, polymer or small molecule, comprising:
reacting a silyl substituted pi-system compound with a highly fluorinated pi-system compound.

2.) The method of claim 1 including completing said reacting of said silyl substituted pi-system compound with said highly fluorinated pi-system compound in presence of a fluoride ion catalyst.

3.) The method of claim 2 including selecting said silyl substituted pi-system compound from a group of compounds with chemical formula 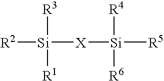
where x is defined as alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof and R¹-R⁶ are the same or different alkene, alkyne, aryl, hetaryl, imine, and combinations thereof or are substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof.

4.) The method of claim 3, including selecting said highly fluorinated pi-system compound from a group of compounds consisting of alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof, and with 2-20 fluorine atoms attached directly to the pi-system.

5.) The method of claim 3, including selecting said highly fluorinated pi-system compound from a group of compounds having chemical formula

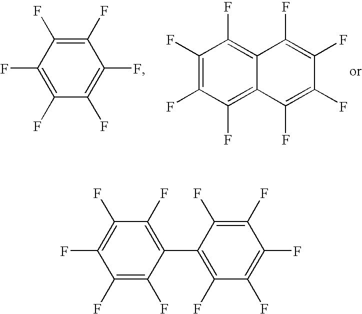

6.) The method of claim 4, including using an inorganic fluoride salt as a fluoride source.

7.) The method of claim 4, including using an organic fluoride salt as a fluoride source.

8.) The method of claim 1 including selecting said silyl substituted pi-system compound from a group of compounds with chemical formula 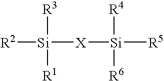
where x is defined as alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof and R¹-R⁶ are the same or different alkene, alkyne, aryl, hetaryl, imine, and combinations thereof or are substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof.

9.) The method of claim 7, including selecting said highly fluorinated pi-system compound from a group of compounds consisting of alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof, and with 2-20 fluorine atoms attached directly to the pi-system.

10.) The method of claim 7, including selecting said highly fluorinated pi-system compound from a group of compounds having chemical formula

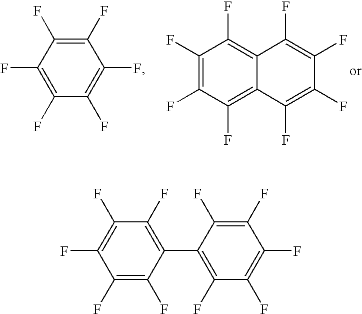

11.) The method of claim 9, including using an inorganic fluoride salt as a fluoride source.

12.) The method of claim 11, including using an organic fluoride salt as a fluoride source.

13.) The method of claim 1, including selecting said highly fluorinated pi-system compound from a group of compounds consisting of alkene, alkyne, aryl, hetaryl, imine, and combinations thereof and bearing substituents including hydrogen, halogen, chalcogen, alkyl with 1-40 carbons, alkoxy with 1-40 carbons, amine with 0-40 carbons, ammonium salt with 0-40 carbons, amide with 1-40 carbons, ester with 1-40 carbons, carboxylic acid with 1-40 carbons, alcohol with 0-40 carbons, aldehyde, ketone with 2-40 carbons, aryl, alkyl-(het)aryl with 3-40 carbons, hetaryl, sulfide, nitro, nitrile, sulfone, sulfoxide, sulfonic acid, sulfonate, and any combination thereof with 2-20 attached fluorine atoms.

14.) The method of claim 1, including selecting said highly fluorinated pi-system compound from a group of compounds having chemical formula

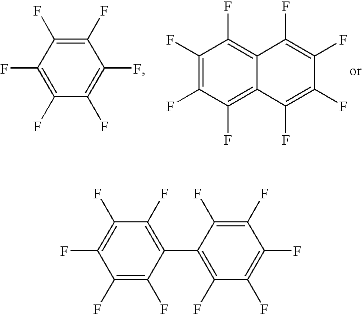

15.) The method of claim 13, including using an inorganic fluoride salt as a fluoride source.

16.) The method of claim 15, including using an organic fluoride salt as a fluoride source.

17.) A monomer, oligomer, polymer of small molecule made by the method of claim 1.

18.) A monomer, oligomer, polymer or small molecule made by the method of claim 1 wherein said monomer, oligomer, polymer or small molecule is uncontaminated with a heavy metal catalyst during production.

19.) A semiconductor made with said monomer, oligomer, polymer or small molecule of claim 17.

20.) A thin film transistor made with said monomer, oligomer, polymer or small molecule of claim 17.

21.) A photovoltaic device made with said monomer, oligomer, polymer or small molecule of claim 17.

22.) A field effect transistor made with said monomer, oligomer, polymer or small molecule of claim 17.

23.) An organic field effect transistor made with said monomer, oligomer, polymer or small molecule of claim 17.

24.) An eluminescent material made with said monomer, oligomer, polymer or small molecule of claim 17.

25.) An organic light emitting diode made with said monomer, oligomer, polymer or small molecule of claim 17.

26.) A liquid crystal display made with said monomer, oligomer, polymer or small molecule of claim 17.

27.) An integrated circuit made with said monomer, oligomer, polymer or small molecule of claim 17.

28.) A radio frequency identification tag made with said monomer, oligomer, polymer or small molecule of claim 17.
